(19) United States
(12) Patent Application Publication
(10) Pub. No.: US 2025/0318058 A1
(43) Pub. Date: Oct. 9, 2025

(54) APPARATUS FOR SECURING AN ELECTRONIC DEVICE AND AN ACCESSORY DEVICE TO A SUPPORT STRUCTURE AND ACCESSORY DEVICE FOR USE THEREWITH

(71) Applicant: UBICQUIA, INC., FORT LAUDERDALE, FL (US)

(72) Inventors: Claudio Santiago Ribeiro, Evanston, IL (US); Steven Kenneth Mackiewicz, Shorewood, IL (US); Stephen M. Oshgan, Arlington Heights, IL (US)

(21) Appl. No.: 19/241,368

(22) Filed: Jun. 17, 2025

Related U.S. Application Data
(63) Continuation-in-part of application No. 17/695,779, filed on Mar. 15, 2022, now Pat. No. 12,336,120.
(63) Continuation-in-part of application No. 29/802,012, filed on Aug. 2, 2021, now Pat. No. D1083579.
(63) Continuation-in-part of application No. 29/881,152, filed on Dec. 28, 2022.
Application No. 17/695,779 is a continuation-in-part of application No. 29/767,115, filed on Jan. 20, 2021, now Pat. No. D1002358.
Application No. 29/802,012 is a continuation-in-part of application No. 29/767,115, filed on Jan. 20, 2021, now Pat. No. D1002358.

(51) Int. Cl. H05K 5/02

(52) U.S. Cl. CPC H05K 5/0204

(57) ABSTRACT

An apparatus for mounting an electronic device and an accessory device to a support structure includes a coupling member, a clamp member, and a latch mechanism. The coupling member includes an elongated electronic device support portion and a clamp support portion. The clamp support portion extends substantially orthogonally from one end of the electronic device support portion. The clamp support portion includes a recessed outward-facing surface and defines an accessory attachment channel bordered on at least one side by the recessed surface. The clamp member includes a base, a pair of clamp portions, and a hinge. The base is coupled to the coupling member's clamp support portion. The hinge pivotally couples first ends of the clamp portions. The latch mechanism is positioned at second ends of the clamp portions and configured to latch the second ends of the clamp portions after the clamp portions are positioned about the support structure.

### CROSS-REFERENCE TO RELATED APPLICATIONS

The present application is a continuation-in-part of U.S. Design patent application Ser. No. 29/802,012, which was filed on Aug. 2, 2021, and is incorporated herein by this reference in its entirety. The present application is also a continuation-in-part of U.S. application Ser. No. 17/695,779, now U.S. Pat. No. 12,336,120, which was filed on Mar. 15, 2022, and is incorporated herein by this reference in its entirety. The present application is further a continuation-in-part of U.S. Design patent application Ser. No. 29/881,152, which was filed on Dec. 28, 2022, and is incorporated herein by this reference in its entirety. U.S. Design patent application Ser. No. 29/802,012 and U.S. application Ser. No. 17/695,779 are continuations-in part of U.S. Design patent application Ser. No. 29/767,115, now U.S. Pat. No. D1,002,358, which was filed on Jan. 20, 2021, and is incorporated herein by this reference in its entirety.

### TECHNICAL FIELD

The present disclosure relates generally to the mounting of electronic devices and accessory devices to support structures and, more particularly, to an apparatus for mounting an electronic device and an accessory device to a support structure, such as a streetlight pole or pole arm, and an accessory device for use with such an apparatus.

### BACKGROUND

Clamping structures are commonly used to mount equipment to structures. In particular, clamping structures can use opposing semi-circular halves that are bolted together on each side around a cylindrical pole section. These halves a sometimes referred to as being U-shaped or horseshoe shaped. To install these a worker generally puts one half on one side of the pole, then aligns the other half with the first half, and passes a respective bolt through each of the opposing ends. This operation generally requires both hands to do. Thus, if the equipment being mounted needs to be held during this process, another person is needed to hold the equipment, or some sort of assistance must be used to hold the equipment being mounted. Types of equipment that are being deployed presently are small cell access node devices and public safety monitoring devices. These devices may be mounted on existing lighting structures used to light roads, sidewalks, parking lots, and parks in urban or city locales. Modern lighting structure includes electrical connectors that can be used to power the electronic devices, which in turn may power their associated accessory devices. However, the use of prior art clamping structures to mount electronic devices and their associated accessory devices to light pole sections is inefficient and may require multiple personnel to install the equipment.

Therefore, a need exists to overcome the problems with the prior art as discussed above.

### BRIEF SUMMARY

Exemplary embodiments of the present disclosure provide an apparatus for mounting an electronic device and an accessory device to a support structure. The apparatus includes a coupling member, a clamp member, and a latch mechanism. The coupling member includes an elongated electronic device support portion and a clamp support portion. The clamp support portion extends substantially orthogonally from one end of the electronic device support portion. The clamp support portion includes a recessed outward-facing surface and defines an accessory attachment channel bordered on at least one side by the recessed outward-facing surface. The clamp member includes a base, a first clamp portion, a second clamp portion, and a hinge (as implemented in an exemplary manner through the interleaving member and the hinge pin). The clamp member's base is coupled to the clamp support portion of the coupling member, and the hinge pivotally couples the first end of the first clamp portion to the first end of the second clamp portion. In some embodiments, the first and second clamp portions are arched. The latch mechanism is positioned at the second end of the first clamp portion and the second end of the second clamp portion. The latch mechanism is configured to latch the second end of the first clamp portion to the second end of the second clamp portion after the first clamp portion and the second clamp portion are positioned about the support structure.

Alternative embodiments of the present disclosure provide a clamp assembly for mounting an electronic device to a pole section of a light structure. The clamp assembly includes a coupling member that has an elongated electronic device support portion that has a first end and a second end. The coupling member also has a clamp support portion that extends from the second end of the electronic device support portion in a direction substantially normal to an elongated direction of the electronic device support portion such that the coupling member may have a substantial “L” shape. The clamp assembly also includes a clamp member that has a base that is coupled to the clamp support portion. The clamp member also has a first clamp portion that has a first end fixed to the base, and a second end that is free. The first clamp portion has a semicircular shape between its first end and its second end. The clamp member also has a second clamp portion including first end that is joined to the first end of the first clamp portion by a hinge. The second clamp portion has a semicircular shape between its first end and its second end. The semicircular shape of the second clamp portion opposes the semicircular shape of the first clamp portion such that the first and second clamp portions define a circle between them when the second ends of the upper and second clamp portions are bought together. The clamp assembly also has a latch mechanism mounted at the second end of the first clamp portion that is moveable and configured to latch the second end of the second clamp portion to the second end of the first clamp portion.

Some exemplary embodiments of the inventive disclosure provide an electronic device mountable to a support structure. The small cell access node device includes a turn-lock electrical connector disposed on a bottom side at a front of the small cell access node device. The small cell access node device also has a pair of parallel tracks along the bottom side, each one of the pair of tracks runs in a direction from a back to the front of the small cell access node device and each have a slot along the track in which to receive a corresponding shuttle. The small cell access node device has a clamp assembly that includes a coupling member. The coupling member has an elongated top portion with a first end and a second end. The coupling member further including a clamp support portion that extends from the second end of the top portion in a direction substantially normal to an elongated direction of the top portion. The coupling member also includes a first shuttle at first end disposed on a top surface of the top portion and coupled into a first one of the pair of tracks, and a second shuttle at second end disposed on the top surface of the top portion and coupled into a second one of the pair of tracks. The shuttles are movable along the tracks and hold the clamp assembly to the bottom side of the small cell access node device. The clamp assembly of the small cell access node device further includes a clamp member that has a base, and the base is coupled to the clamp support portion of the coupling member. The clamp member further has a first clamp portion having a first end fixed to the base and a second end that is positioned closer to the top portion of the coupling member than the first end. The clamp member also has a second clamp portion that has a first end that is coupled to the first end of the first clamp portion by a hinge joint such that the second clamp portion is moveable about the hinge joint. The second clamp portion also has a second end that mates against the second end of the first clamp portion when the second clamp portion is in a closed position. The clamp assembly further includes a latch that is anchored at the second end of the first clamp portion, and that is configured to engage the second end of the lower clamp member when the lower clamp member is in the closed position.

Some other exemplary embodiments of the present disclosure provide a clamp assembly for mounting on a pole section of a lighting structure that includes a coupling member having a top portion. The top portion has a first end, a second end, and a top surface. The coupling member also has a clamp support portion that extends from the top portion at the second end of the top portion, opposite the top surface, at substantially a right angle to the top portion. The clamp assembly further includes a clamp member that has a base that is slidably coupled to the clamp support portion. The clamp member has a first clamp portion having a first end which is fixed to the base, and a second end that is closer to the top portion of the coupling member than the first end of the first clamp portion is to the top portion. The first clamp portion has a semi-circular inner face between the first and second ends of the first clamp portion. The clamp member further has a second clamp portion that has a first end connected to the first end of the first clamp portion at a hinge joint. The second clamp portion is movable about the hinge joint between an open and a closed position. In the closed position a second end of the second clamp portion is against the second end of the first clamp portion. The second clamp portion has a semi-circular inner face between the first and second ends of the second clamp portion. The clamp assembly further has a latch member with a first end anchored at a hinge joint at the second end of the first clamp portion. The latch member is movable about the hinge joint between an unlatched position and a latched position, and is configured to latch the second end of the second clamp portion against the second end of the first clamp portion.

Although the present disclosure illustrates and describes a clamp assembly for mounting a small cell access node device on an outdoor light fixture, it is, nevertheless, not intended to be limited to the details shown because various modifications and structural changes may be made therein without departing from the spirit of the disclosure and while remaining within the scope and range of equivalents of the claims. Additionally, well-known elements of the invention will not be described in detail or will be omitted so as not to obscure the relevant details of the invention.

Features that are considered characteristic of the invention are set forth in the appended claims. As required, detailed embodiments of the small cell housing are disclosed herein; however, it is to be understood that the disclosed embodiments are merely exemplary, and the housing may be embodied in various forms. Therefore, specific structural and functional details disclosed herein are not to be interpreted as limiting, but merely as a basis for the claims and as a representative basis for teaching one of ordinary skill in the art to variously employ the claimed invention in appropriately detailed structures. Further, the terms and phrases used herein are not intended to be limiting; but rather, to provide an understandable description of the disclosure. While the specification concludes with claims defining the features of the invention, it is believed that the claimed invention will be better understood from a consideration of the following description in conjunction with the drawing figures, in which like reference numerals are carried forward. The figures of the drawings are not drawn to scale.

The terminology used herein is for the purpose of describing particular embodiments only and is not intended to be limiting. The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically. The term “providing” is defined herein in its broadest sense, e.g., bringing/coming into physical existence, making available, and/or supplying to someone or something, in whole or in multiple parts at once or over a period of time.

As used in this description, unless otherwise specified, azimuth or positional relationships indicated by terms such as “up”, “down”, “left”, “right”, “inside”, “outside”, “front”, “back”, “head”, “tail” and so on, are azimuth or positional relationships based on the drawings, which are only to facilitate description of the embodiments of the present invention and simplify the description, but not to indicate or imply that the devices or components must have a specific azimuth, or be constructed or operated in the specific azimuth, which thus cannot be understood as a limitation to the embodiments of the present invention. Furthermore, terms such as “first”, “second,” “third,” and so on are only used for descriptive purposes and should not be construed as indicating or implying relative importance.

As used in this description, unless otherwise clearly defined and limited, terms such as “installed”, “coupled”, “connected” should be broadly interpreted, for example, it may be fixedly connected, or may be detachably connected, or integrally connected; it may be mechanically connected, or may be electrically connected; it may be directly connected or may be indirectly connected via an intermediate medium. As used herein, the terms “about” or “approximately” apply to all numeric values, whether or not explicitly indicated. These terms generally refer to a range of numbers that one of skill in the art would consider equivalent to the recited values (i.e., having the same function or result). In many instances these terms may include numbers that are rounded to the nearest significant figure. In this document, the term “longitudinal” should be understood to mean in a direction corresponding to an elongated direction of the device. Those skilled in the art can understand the specific meanings of the above-mentioned terms in the embodiments of the present disclosure according to the specific circumstances.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and explain various principles and advantages all in accordance with the present disclosure.

FIG. 1 is a front elevational view of a clamp assembly with its clamp member in an open position, in accordance with an exemplary embodiment of the present disclosure.

FIG. 2 is a front elevational view of the clamp assembly of FIG. 1 with the clamp member in a closed position, in accordance with an exemplary embodiment of the present disclosure.

FIG. 3 is a perspective view of the clamp assembly of FIG. 1 with the clamp member in the closed position, in accordance with an exemplary embodiment of the present disclosure.

FIG. 4 is an exploded view of a coupling member of the clamp assembly of FIG. 1, in accordance with an additional exemplary embodiment of the present disclosure.

FIG. 5 is an exploded view of a clamp member of the clamp assembly of FIG. 1, in accordance with a further exemplary embodiment of the present disclosure.

FIG. 6 shows an exemplary electronic device that includes the clamp assembly of FIG. 1 in a position prior to securing the electronic device to a streetlight, in accordance with some exemplary embodiments of the present disclosure.

FIG. 7 shows the exemplary electronic device of FIG. 6 as connected to a light fixture of the streetlight with the clamp assembly open and positioned around a section of a light pole, in accordance with some exemplary embodiments of the present disclosure.

FIG. 8 shows the exemplary electronic device of FIG. 6 secured to the streetlight with the clamp closed, in accordance with some embodiments of the present disclosure.

FIG. 9 shows the exemplary clamp assembly of FIG. 1 with an exemplary electronic device and an exemplary accessory device secured thereto, in accordance with some exemplary embodiments of the present disclosure.

FIG. 10 shows a bottom, rear perspective view of a clamp assembly with an exemplary accessory device partially installed in a channel of the clamp assembly and an enlarged view of an exemplary mechanism for securing the accessory device to an upper portion of the clamp assembly after installation of the accessory device in the clamp assembly channel, in accordance with other exemplary embodiments of the present disclosure.

FIG. 11 shows an enlarged view of a lower section of the channel of the clamp assembly of FIG. 10 illustrating insertion and securing of a hook member of the accessory device to a receptacle structure in the clamp assembly's channel, in accordance with further exemplary embodiments of the present disclosure.

FIG. 12 shows a front view of a clamp assembly with the clamp member in a closed position and another exemplary accessory device including at least one camera installed within a channel of the clamp assembly, in accordance with other exemplary embodiments of the present disclosure.

FIG. 13 shows a top, front, left, perspective view of a clamp assembly with the clamp member in a closed position and an alternative exemplary camera accessory device including two cameras installed within a channel of the clamp assembly, in accordance with other exemplary embodiments of the present disclosure.

FIG. 14 shows a front view of an exemplary accessory device including a downward-facing camera together with a cutaway view of the lower portion of the clamp assembly's channel as shown in FIGS. 10 and 11 illustrating retention of the accessory device's hook member by the receptacle structure in the clamp assembly's channel, in accordance with additional exemplary embodiments of the present disclosure.

### DETAILED DESCRIPTION

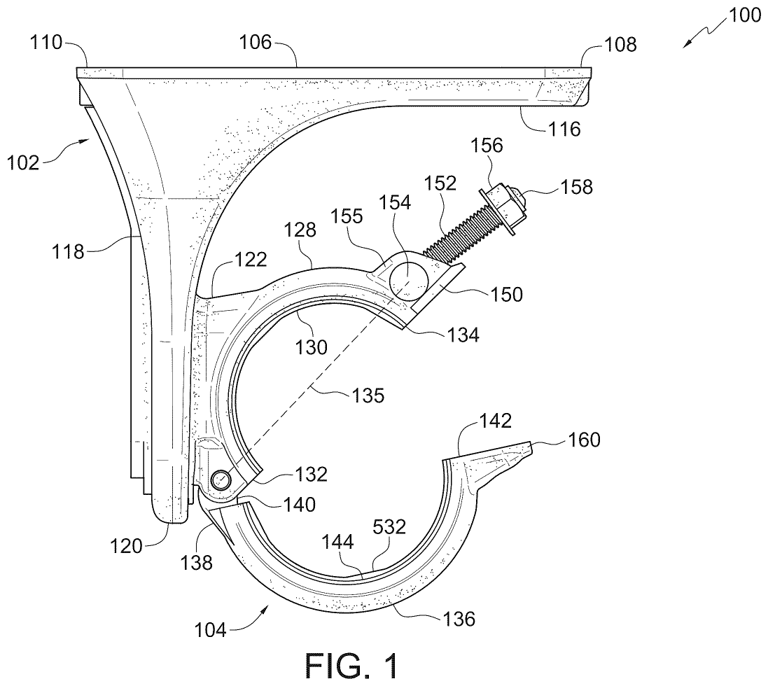

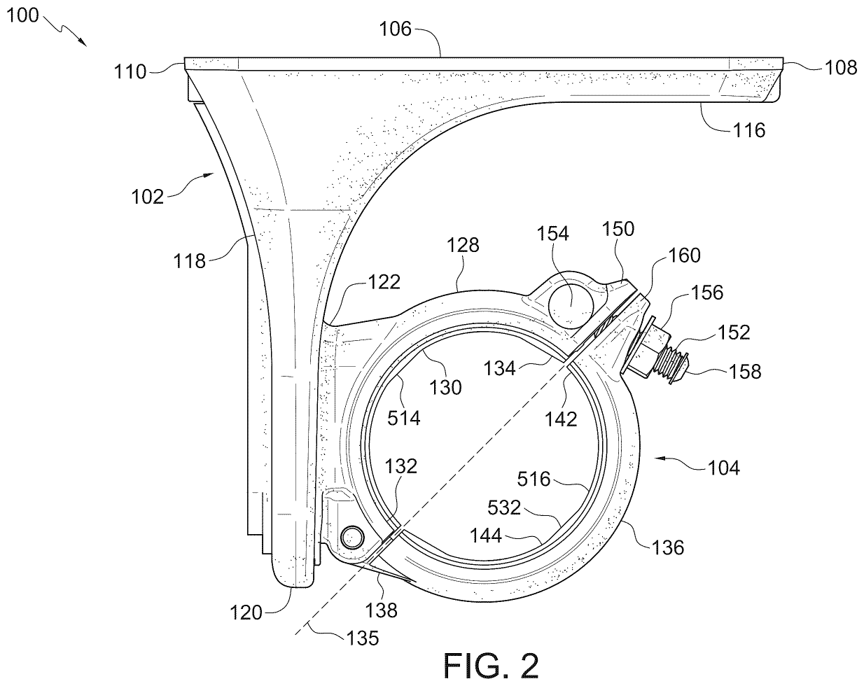

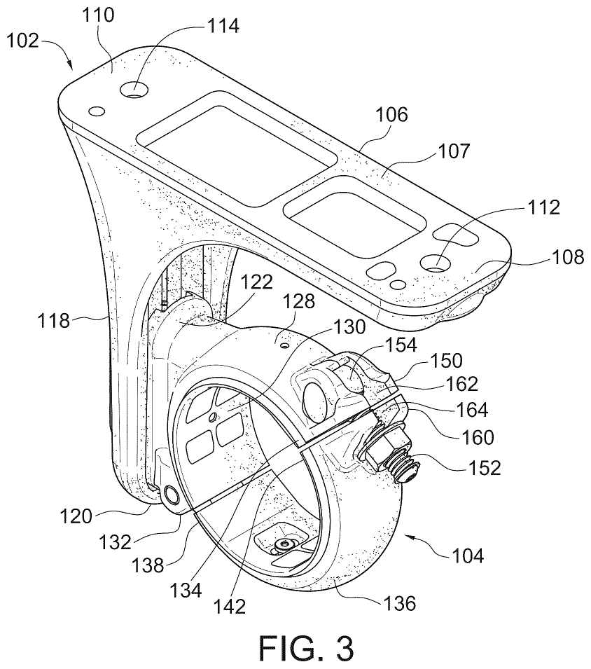

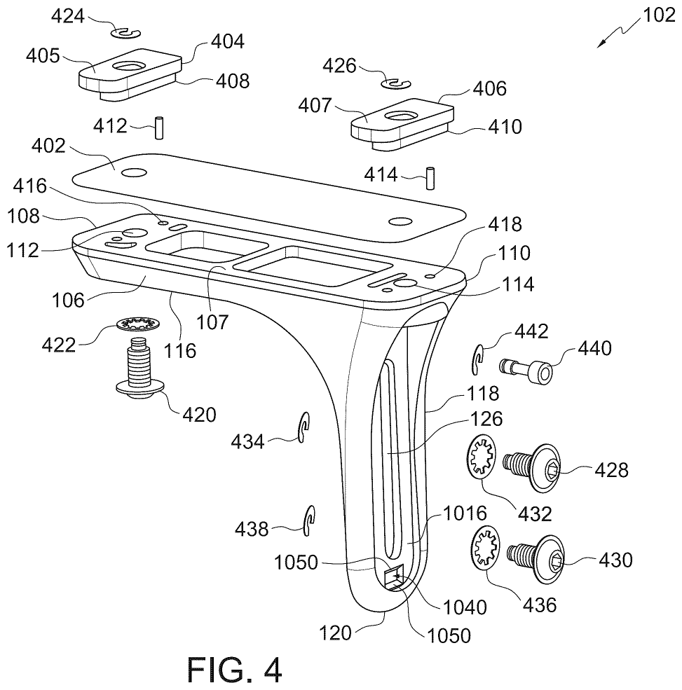

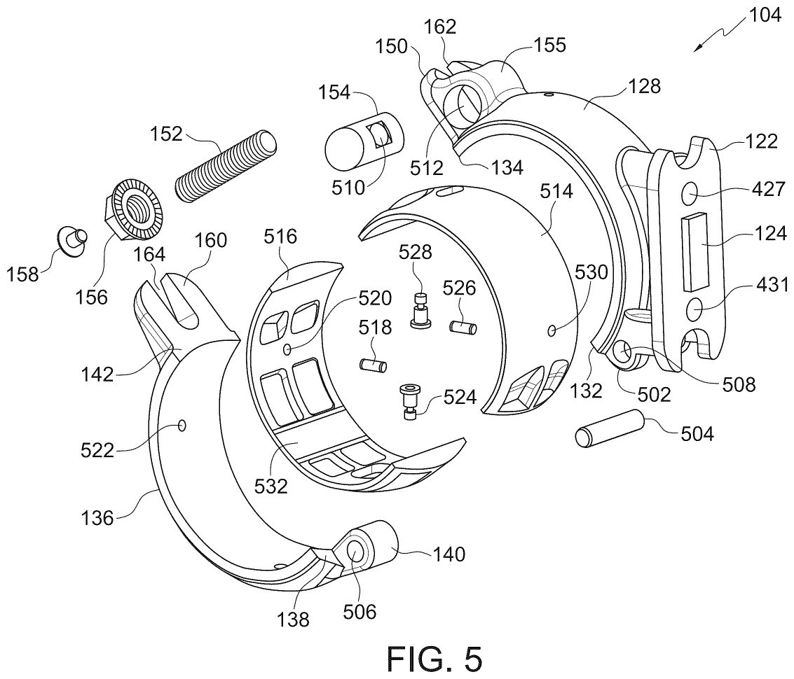

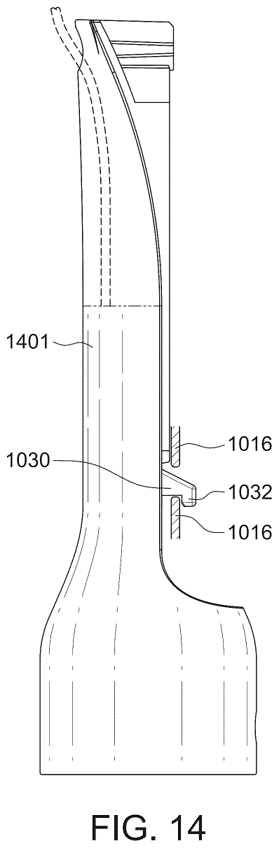

FIG. 1 is a front elevational view of a clamp assembly 100 with its clamp member 104 in an open position, in accordance with an exemplary embodiment of the present disclosure. The clamp assembly 100 includes a coupling member 102 and the clamp member 104. The coupling member 102 couples the clamp assembly 100 to the bottom of an electronic device, such as an aerially-mountable small cell access node or other electronic device, and the clamp member 104 is configured to encircle or surround, and clamp to, a support structure, such as pole of a streetlight. FIGS. 2 and 3 show alternative views of the clamp assembly 100 with the clamp member 104 closed as it would be when clamped to a pole section of a lighting fixture. FIG. 4 shows an exploded sub-assembly view of the coupling member 102, and FIG. 5 shows and exploded sub-assembly view of the clamp member 104. Some of the features referenced herein may be viewable in one or more of FIGS. 1-14 but not necessarily all of the drawings.

The coupling member 102 includes an electronic device support portion 106 having a generally flat, top surface 107. The electronic device support portion 106 has a first end 108 and a second end 110 opposite the first end 108. The first and second ends 108, 110 generally have a width in a direction normal to a direction from the first end 108 to the second end 110, and the widths of the first and second ends 108, 110 are substantially less than a length between the first and second ends 108, 110. As a result, the top surface 107 can be generally rectangular, but can also be elliptical or oval or have another shape. In some applications the top portion 106 is oriented to be generally horizontal with the top surface 107 being generally flat. The electronic device support portion 106 at the first end 108, has a bottom 116 that may be generally flat and parallel to the top surface 107 along some of the electronic device support portion 106 from the first end 108 toward the second end 110. A first opening 112 at the first end passes through the electronic device support portion 106, from the top surface 107 to the bottom 116. Likewise, a second opening 114 at the second end 110 passes through the electronic device support portion 106 as well. The first and second openings 112, 114 allow fasteners to pass through the electronic device support portion 106 to facilitate attachment to the bottom of an electronic device.

A clamp support portion 118 extends from the electronic device support portion 106 at a generally right angle to the elongated direction of the electronic device support portion 106 (i.e., the direction between the ends 108, 110). In particular, the clamp support portion 118 extends from the electronic device support portion 106 opposite the top surface 107 near the second end 110, and is off center, relative to the first and second ends 108, 110 of the electronic device support portion 106. The clamp support portion 118 may depend from or be attached to the electronic device support portion 106. The clamp support portion 118 has a distal end or bottom 120 that terminates the clamp support portion 118, and the clamp support portion 118 is configured couple to the clamp member 104 and support the clamp member 104. Thus, when the clamp member 104 is clamped to a pole section of a light fixture, the electronic device support portion 106 can be coupled to the bottom of the electronic device, and the clamp assembly 100 acts to secure the electronic device to the support structure (e.g., a pole section of a streetlight).

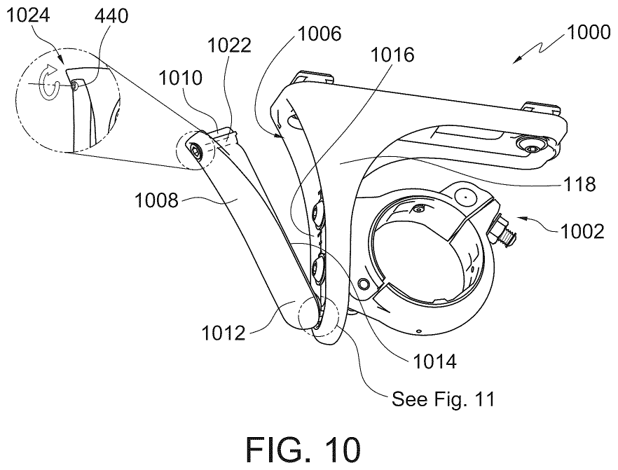

The clamp member 104 includes a base portion 122 and two pivotally or hingeably coupled clamp portions 128, 136. The base portion 122 includes a protrusion 124 (shown in an exemplary rectangular shape in FIG. 5) along its side opposite the side to which the base portion is coupled to a first clamp portion 128. The protrusion 124 is configured to fit within a corresponding slot 126 defined by the clamp support portion 118 through an inward-facing surface and an outward-facing surface 1016 thereof. In one exemplary embodiment, the protrusion 124 is shorter than the length of the slot 126 in the clamp support portion 118 to allow the base portion 122 of the clamp member 104 to be height-adjustable relative to the position of the electronic device support portion 106. That is, the base portion 122 of the clamp member 104 can be slid up and down along a height or length of the clamp support portion 118 and then be fixed at a desired position to allow leveling of an electronic device secured to the electronic device support portion 106 of the coupling member 102. As shown in FIGS. 4 and 10, the outside surface 1016 of the clamp support portion 118 is preferably recessed to form a channel 1006 for receiving a housing of an accessory device, such as a cover, a camera, a multi-camera device, an antenna, a speaker, a solar panel unit (e.g., for generating and storing back-up power for the electronic device 602, 906), and so forth. According to some embodiments, the recessed outward-facing surface 1016 bordering the channel 1006 of the clamp support portion 118 may define the slot 126 of the clamp support portion 118.

The base portion 122 is joined to the first clamp portion 128, which has an engagement surface 130 of a desired geometric shape (e.g. arched). The first clamp portion may include a first bushing component 514 or may accommodate attachment of a first bushing component 514. The first bushing component 514 may be made of metal, such as aluminum, or any other material having a high coefficient of friction and being slightly compressible or resilient. The first clamp portion 128 has a first end 132 that is proximate to the bottom or lower end of the base portion 122. From the first end 132, the first clamp portion 128 follows an arched path to a second end 134. The second end 134 of the first clamp portion 128 is closer to the top portion 106 of the coupling member 102 than is the first end 132 of the first clamp portion 128. As such, a line 135 from the first end 132 to the second end 134 of the first clamp portion 128 may be at about a forty-five degree angle to either the elongated direction of the top portion 106 of the coupling member 102 or the elongated direction of the clamp support portion 118, since they are at a generally right angle to each other. As a result, the clamp assembly 100 only needs to be moved or slid a small distance, as indicated by dashed line 202, in order to pass over a support structure, such as a section of a pole, as compared to line 204 if the first ends 132, 138 of the clamp portions 128, 136 were at the same height as their respective second ends 134, 142.

The second clamp portion 136, which may be positioned lower than the first clamp portion 134 during use of the clamp assembly 100, is likewise arched and may include or accommodate attachment of a second bushing component 516. The second bushing component 516 may be made of metal, such as aluminum, or any other material having a high coefficient of friction and optionally being slightly compressible or resilient. The material used and the geometric shape selected for implementing the bushing components 514, 516 should be sufficient to resist movement or rotation of the clamp member 104 relative to the support structure to which the clamp member 104 is secured. The second clamp portion 136 has a first end 138 that is proximate the first end 132 of the first clamp portion 128 and is hingeably joined to the first clamp portion 128 by an interleaving member 140 that extends from the first end 138 of the second clamp portion 136 between one or more extensions 502, which extend from the first end 132 of the first clamp portion 128. A hinge pin 504 may be included to pass through lateral openings 506 and 508 of the interleaving member 140 and the extension(s) 502, respectively. Thus, the second clamp portion 136 is moveable relative to the first clamp portion 128 to open and close the clamp member 104. In the closed position, the second end 142 of the second clamp portion 136 will be against the second end 134 of the upper clamp member 128. The second clamp portion 136 is movable, about the hinge pin 504, relative to the first clamp portion 128, between a closed position as shown in FIG. 2, and an open position. FIG. 1 shows the second clamp portion 136 in a partially open position, and it can be opened further to allow a light fixture pole to fit within the clamp member 104, and then closed to clamp the clamp member 104 on the pole. Thus, the second clamp portion 136 is moveable between an open position, such as that shown in FIG. 1, and which can be opened further than that shown. In particular, the lower clamp member 136 is movable such that a distance between the second ends 134, 142 is larger than the diameter of the circle defined between the first and second clamp portions when the second clamp portion is closed, as shown in FIG. 2, with the second end 134, 142 against each other.

To hold the lower clamp member 136 in the closed position, a latch is provided that includes a threaded rod 152 that is anchored at one end in a transverse cylinder 154, which has a threaded opening 510 through the cylinder 154 to receive the threaded end of the threaded rod 152. The cylinder 154 is held by a boss 155 at the second end 134 of the first clamp portion 128 to form a hinge joint at the second 134 of the first clamp portion. The hinge joint allows the threaded rod 152, acting as a latch member, to rotate about the hinge joint, meaning the free end or latching end of the threaded rod 152 can rotate around the hinge joint location. The boss 155 has a corresponding transverse hole 512 in which the cylinder sits, allowing the cylinder to rotate in place. The boss 155 includes a slot 162 along its top to allow the threaded rod 152 to rotate about the transverse axis of the cylinder 154. The boss 155 is adjacent an outward extension 150 at the second end 134 through with the slot 162 passes. The second clamp portion 136, at its second end 142, includes an outward or radial extension 150 that abuts the radial extension 150 of the first clamp portion 128 when the lower claim portion 136 is in the closed position (e.g., as illustrated in FIG. 2). The slot 164 of the radial extension 150 of the second clamp portion 136 aligns with the slot 162 of the radial extension 150 of the first clamp portion 128. As a result, the threaded rod 152 can be positioned in an extended position as shown in FIG. 1, when the second clamp portion 136 is in an open position, and then rotated to a latch position as shown in FIGS. 2-3 to latch the second clamp portion 136 in the closed position. A latch nut 156 disposed on the threaded rod 152 is retained on the threaded rod 152, which is tightened against the backside of the radial extension 160 to retain the second clamp portion 136 in the closed position. A retaining cap 158 can be placed at the distal end of the threaded rod 152 to prevent the latch nut 156 from coming off the threaded rod 152.

In FIG. 4, additional features of the coupling member 102 are shown, in accordance with some alternative embodiments. For example, a non-conductive spacer 402 can be placed over the top surface 107 of the top portion 106 of the coupling member 102 to provide electrical isolation between the top surface 107 of the top portion 106 of the coupling member 102 and a pair of shuttles 404, 406 that support an electronic device mounted to the top portion 106 of the coupling member 102. The pair of shuttles 404, 406 may be disposed at the first end 108 and second end 110, respectively, of the top portion 106. The shuttles sit on top of the top portion 106, over the top surface 107, and have an outward extending top portion 405, 407 over a connecting portion 408, 410, respectively. The outward extending portions fit into captured rails in the bottom of the small cell access node device. Pins 412, 414 sit partly in the connecting portions 408, 410, and partly in the top portion 106 at the top surface 107 to prevent the shuttles 404, 406 from turning. A threaded fastener 420 can pass through opening 112 at the first end 108 of the top portion to retain shuttle 404. A washer 422 can be disposed on the threaded shank of the threaded fastener 420 at the bottom of the top portion 106, while a C clip 424 is used on the distal end of the threaded shank to retain the shuttle 404 on the threaded shank of the threaded fastener 420. Another threaded fastener 420 can be used to retain shuttle 406, passing through opening 114 at the second end 110 of the top portion 106 of the coupling member 104.

To hold the clamp member 104 to the coupling member 102 threaded fasteners 428, 430 pass through slot 126 into holes 427, 431 on base 122 of the clamp member 102 (see FIG. 5). Washers 432, 436, and C clips 434, 438 can be used to retain the threaded fasteners 428, 430 in place, once adjusted. The threaded fasteners 428, 430 can be loosened to allow the base 122 of the clamp member 104 to move vertically along the clamp support portion 118 to an optimum position and then the threaded fasteners 428, 430 can be tightened to hold the clamp member 104 in place. A clamp cover screw 440 can be used to hold a cover 1008 or other accessory device over the threaded fasteners 428, 430 and the exterior side of the clamp support portion 118. A retaining clip 442 can be used to retain the clamp cover screw 440.

FIG. 5 is an exploded view of the exemplary clamp member 104 of the clamp assembly 100, in accordance with exemplary embodiments of the present disclosure. In FIG. 5, the bushing components 514, 516 are secured in their respective clamp portions 128, 136. The first and second bushing components 514, 516 can be selected to fit the clamp onto a variety of sizes and shapes of support structures, such as light poles. That is, light poles are generally cylindrical or have a rounded rectangular shape but may vary in diameter. To obtain a proper clamp force on the pole section, the characteristics, such as shape and thickness, of the bushing components 514, 516 may be selected for an optimum fit. That is, the bushing components 514, 516, when together (i.e., when the clamp is closed), will form a hoop, ring, rounded rectangle or other desired shape around the support structure, such that the bushing formed by the bushing components 514, 516 has an inner diameter or other inner dimension that is about equal to the outer diameter or dimension of the support structure, and has an outer diameter or other dimension that is the same size as the diameter or dimension of the opening formed be the first and second clamp portions 128, 136 (without the bushing components 514, 516). In some embodiments, the bushing components 514, 516 can be made of aluminum and are aligned and secured in their respective clamp portion 128, 136. For example, second bushing component 516 has an alignment hole 520 that aligns with a corresponding alignment hole 522 in the inner face of the second clamp portion 136. A pin 518 extends through both of the alignment holes 520, 522 to align the bushing component 516 against the inner face of the second clamp portion 136. A clamp insert bolt 524 also passes through the bushing component516 and into the clamp portion to secure the bushing component 516 to the second clamp portion 136. Similarly, alignment pin 526 passes through alignment hole 530 in the first bushing component 514, which is further secured to the first clamp portion by clamp insert bolt 528 which screws into a threaded hole in the first clamp portion and passes through the first bushing component 514. To further secure the clamp to the light pole, the bushing components 514, 516, which generally include a circular inner diameter or shape, can have one or more flat facets 532 which can further ensure secure clamping in view of the tolerance range of light pole diameters.

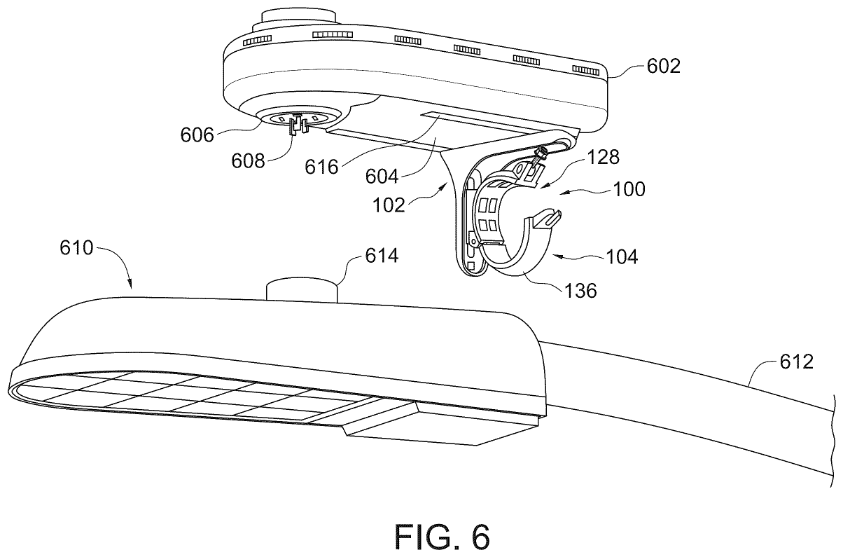

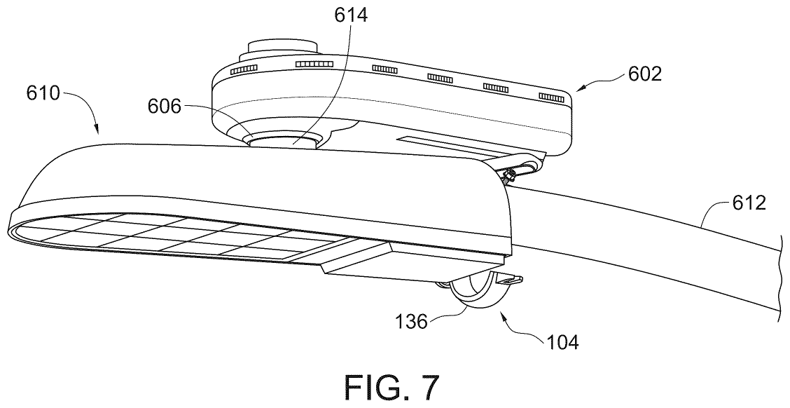

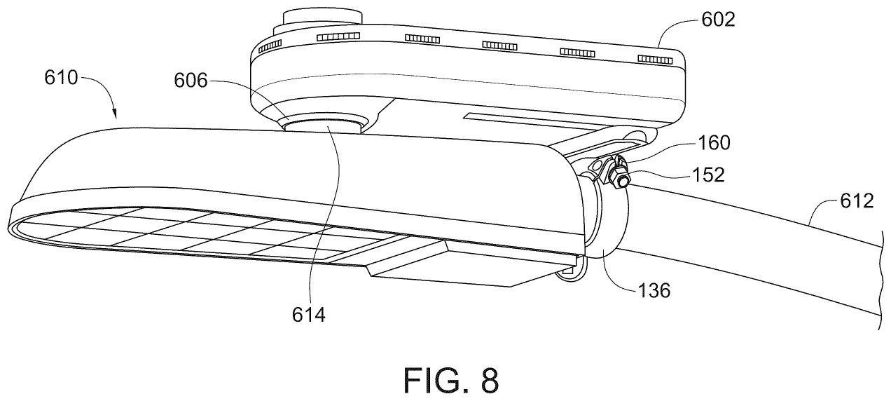

FIGS. 6-8 shows an electronic device, such as, but not limited to, a small cell access node device, using a clamp assembly 100 being installed on a streetlight, in sequence. FIG. 6 shows the clamp assembly 100 open, and prior to connecting the electronic device 602 to the streetlight; FIG. 7 shows the electronic device 602 connected to a light fixture of the streetlight but with the clamp assembly 100 still open; and FIG. 8 shows the electronic device 602 connected to the streetlight and with the clamp assembly 100 closed. The electronic device 602 may be a wireless telecommunications device that provides a local cell of communication access for nearby mobile devices and connects to a telecommunications network for both voice and data communications. For example, the electronic device 602 may provide a wireless air interface in accordance with the standard known as “5G,” which supports a fifth generation of mobile wireless communication. According to an alternative embodiment, the electronic device 602 may be an edge computing platform for use in a public safety system that provides license plate recognition and situational awareness monitoring. According to one exemplary embodiment, the streetlight may have a substantially vertical pole section 612 that is terminated by a light fixture 610. The light fixture 610 may include an electrical connector 614 on its top side. The pole section 612 can be mounted to a building or joined to a vertical pole section that is erected from a ground base.

According to one exemplary embodiment, the electronic device 602 may include, on its bottom side, an electrical connector site 606 that has turn-lock prongs 608 that mate with corresponding electrical connector features in the connector 614 of the light fixture 610. In general, the connector 614 and mating connector site 606 are configured to come together vertically such that the prongs 608 enter receptacles in the connector 614, and then the electronic device 602 is rotated about the connector in a plane normal to the vertical direction to lock the prongs 608 in place. In some embodiments, the connector 614 can be a socket as specified by the National Electrical Manufacturers Association (NEMA) in accordance with standard C136.4 or C136.55 of the American National Standard Institute (ANSI). Thus, in FIG. 6, the clamp assembly 100 is shown in an exemplary manner, above the pole section 612, but also to the side, while connection site 606 is directly over and vertically aligned with connector 614 so that prongs 608 will properly engage with mating electrical connector features in the connector 614 as shown in FIG. 7.

The clamp assembly 100 is mounted on the bottom 604 of the electronic device 602. On the bottom 604 of the electronic device 602 there are two parallel tracks 616 that are configured to receive therein the top portion 405, 407 of the shuttles 404, 406 while the connecting portions 408, 410 of the shuttles 404, 406 pass through a slot along each track 616. The shuttles 404, 406 can move along the track 6161, which allows the coupling member 102 of the clamp assembly 100 (and therefore the clamp assembly 100 itself) to be positioned at an optimum or desired point along the tracks 616. In FIG. 6, with the electronic device 602 positioned over the light fixture, and turned such that, while the connection site 606 is directly over the connector 614, the back end of the electronic device 602 and the clamp assembly 100 are offset to the side of the pole section 612. Further, the second clamp portion 136 of the clamp member 104 is open, substantially as shown in FIG. 1 so that the pole section can fit between the upper and lower claim portion 128, 136. Accordingly, from the position shown in FIG. 6, the electronic device 602 is lowered such the electrical connection at connection site 606 and the connector 614 on the lamp 610 is made, and then the electronic device 602 is rotated to lock the prong 608 into the connector 614, and at the same time, move the first clamp portion 128 over the pole section 612, and the second clamp portion 136 under the pole section 612 to the position shown in FIG. 7. In the position shown in FIG. 7, electrical power is provided to the electronic device 602 from the lamp 610 through connector 614. The locking aspect of the prongs 608 and connector 614 provide a mechanical lock prevents the front end of the electronic device 602 from separating away from the lamp 610. To complete the mounting of the electronic device 602 onto the light fixture, the second clamp portion 136 is raised to close the clamp member 104, and the threaded rod 152 is moved so that the latch nut 156 can be tightened against the outer side of the radial extension 160 to close the clamp portion 128, 136 together, such that the clamp assembly is substantially in the state shown in FIG. 2. The position of the clamp member 104 in the coupling member 102 can then be adjusted to level the electronic device 602. With the clamp assembly 100 clamped onto the pole section 612, the electronic device 602 can then be levelled and is then ready for operation.

The clamp assembly 100 therefore provides the benefit of being able to adjust the position of the clamp assembly 100 relative to the electronic device 602, and to adjust the position of the clamp member on the coupling member to be able to level the electronic device 602. The configuration of the first and second clamp portions 128, 136 allows for single handed closure of the clamp; an installer can lift the second clamp portion 136 to close the clamp portions 128, 136 together with the fingers of one hand and while holding the second clamp portion in the closed position, use their thumb to move the threaded rod 152 into the latch position, and the tighten the latch nut 156 with their thumb as well. Once the latch nut is “thumb tight,” the installer can let go of the lower clamp member 136 and use a tool (wrench) to tighten the latch nut 156 to a desired torque. Thus, the inventive clamp assembly 100 allows for simple mounting, including leveling, of an electronic device, such as a small cell access node device, onto a light fixture. By positioning the first clamp portion with the first end lower than the second (free) end, the height that the small cell access node device needs to be lifted for the second end of the first clamp portion to pass over the pole section is reduced, which puts less torque and stress on the electrical connectors when mounting the small cell access node device.

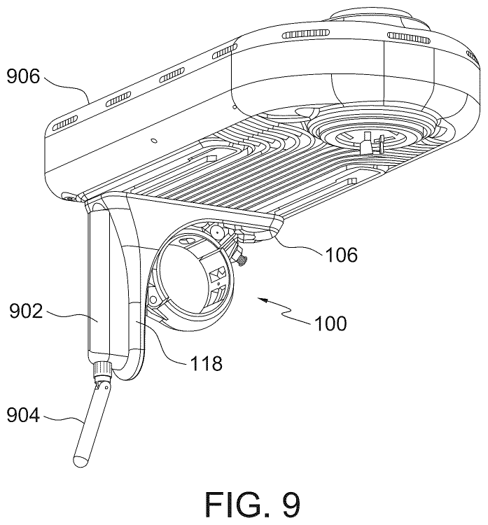

FIG. 9 shows the exemplary clamp assembly 100 of FIG. 1 with an exemplary electronic device 906 and an exemplary accessory device 902 secured thereto, in accordance with some exemplary embodiments of the present disclosure. As shown in FIGS. 9 and 10, a housing of the accessory device 902 is installed at least partially within an accessory channel 1006 defined by a recessed outside surface 1016 of the clamp support portion 118 of the coupling member 102, and the electronic device 906 is secured to the electronic device support portion 106 of the coupling member 102. The electronic device 906 may be a small cell access node or other electronic device (e.g., a processor-based edge computing device or multi-function platform) connectable to a support structure, such as a streetlight pole, by way of the clamp assembly 100. In the exemplary embodiment shown in FIG. 9, the accessory device 902 may be a wireless communication device that utilizes its own antenna 904 to transmit and/or receive wireless signals. The housing of the electronic device 902 is preferably configured to reside at least partially within the channel 1006 of the clamp support portion 118 and optionally against the recessed outside surface 1016 of the clamp support portion 118.

Referring to FIGS. 1 and 10, an apparatus for mounting an electronic device to a support structure, is shown. The apparatus can be in the form of a clamp assembly 100, 1000 and can include: a coupling member 102 having an elongated electronic device support portion 106 and a clamp support portion 118, the electronic device support portion 106 having a first end 108 and a second end 110, the clamp support portion 118 extending from the second end 110 of the electronic device support portion 106 in a direction substantially normal to the electronic device support portion 106; a clamp member 104 including a base 122, a first clamp portion 128, a second clamp portion 136, such that a shape of the second clamp portion opposes a shape of the first clamp portion; and a latch mechanism 1002 positioned on the first clamp portion 128 and the second clamp portion 136, configured to latch the first clamp portion 128 with the second clamp portion 136 when positioned about a support structure.

Advantageously, in one embodiment, an integrated and robust structure is provided with an enhanced accessory device with desirable features that can be configured to withstand a harsh outdoor environment. The mating connection can contribute to an aerodynamic design for minimal wind drag.

The accessory device 1004 includes a housing 1008 and an integrated or attached hook member 1018. The housing 1008 may have an upper section 1010 and a lower section 1012, the cover including a periphery 1014 facing inwardly configured to be partially received in a recess (or passageway) 1006 of the clamp support portion 118. Beneficially, this structure can provide a secure cover and protection of the contents in the accessory channel 1006 from the elements and weather and can be configured to be aerodynamic providing minimal wind drag. The contents can include wires, cables, wire or cable connectors and components connecting the electronic device 900 and the accessory device 1004.

As shown in FIG. 10, the accessory device 1004 includes a housing 1008 and a hook member 1018 integrated into or attached to the lower section 1012 configured to be received and connected to a receptacle structure 1020 of the clamp support portion 118. Advantageously, this structure facilitates temporary and more permanent attachment. For example, the hook member 1018 allows temporary connection providing an open cover (door) 1008 for an installer or service person access to the interior passageway or recess 1016 for making fine or course adjustments, aligning cables or making cable and/or electrical connections, etc. Upon completion, an installer can close the cover 1008 and fasten the screw 440 at upper section 1010, for a secure closure. In more detail, the accessory device 1004 can include an opening 1022 which allows a screw 440 or other fastener to travel therethrough allowing the upper section 1010 of the accessory device 1004 to be fastened to the clamp support portion 118. Such structure facilitates attachment during installation or service. For example, an installer only needs one hand to fasten the upper section 1010 of the accessory device 1004 to the clamp support portion 118.

In another exemplary embodiment, the accessory device 1004 includes a hook member 1018 containing a horizontal portion 1030 and a vertical portion 1032 configured to be inserted through a hook receiving aperture 1040 of the clamp support portion's recessed outer surface 1016. The vertical portion 1032 is shorter than the horizontal portion 1030. The hook member 1018 may also include a flat front portion 1034. This structure provides a means of attaching the hook member 1018 with a substantially complementarily configured receptacle structure, thus providing an enhanced two surface connection in which the horizontal portion 1030 of the hook member 1018 contacts a horizonal wall 1036 or surface of a set of walls 1036, 1050 defining the hook receiving aperture 1040 in the recessed outer surface 1016 of the clamp support portion 118 and the vertical portion 1032 of the hook member 1018 engages the inside surface of the clamp support portion 118. In more detail, the hook member 1018 can be automatically set and interconnected when aligned and inserted in the hook receiving aperture 1040.

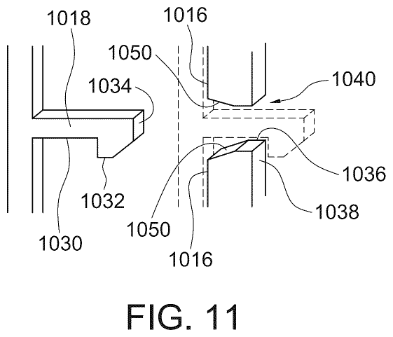

In FIG. 11, a hook set connection includes a temporary connection with an open cover 1008, which allows access to an interior area or passageway provided by recess 1016 of the clamp support portion 118, for facilitating inspection, troubleshooting, installation and/or maintenance, for example.

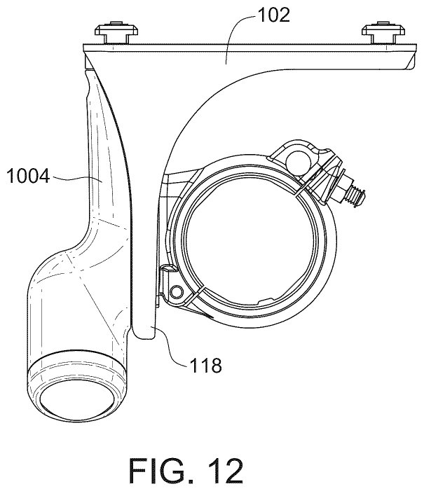

As shown in FIGS. 12-14, the accessory device 1004, 1401 can include at least one of a camera, multiple cameras, lighting, antenna structure, power cell, solar collector and the like. Advantageously, the accessory device 1004 can provide an integrated and robust structure with highly desirable features and accessories depending on the application.

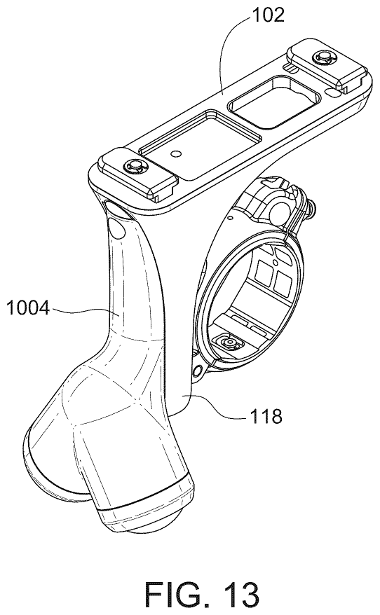

In FIGS. 12 and 13, an exemplary embodiment of a mounting apparatus 100 is shown with an accessory device 1004 installed. In the embodiment shown, the accessory device 1004 includes at least one camera and may include a pair of cameras as more clearly illustrated in FIG. 13.

An exemplary method for mounting an electronic device and an accessory device to a support structure includes steps of: connecting a coupling member 102 to an electronic device, the coupling member 102 having a support portion 106 and a clamp support portion 118, the clamp support portion 118 extending from an end 110 of the support portion 106 in a direction substantially normal to the support portion 106; coupling a clamp member 104 to the clamp support portion 118, the clamp member 104 including a first clamp portion 128 and a second clamp portion 136, such that a shape of the second clamp portion opposes a shape of the first clamp portion; latching the clamp member 104 about a support structure 612 with a latch mechanism; and attaching an accessory device to an outer portion of the clamp support portion 118. Advantageously, the method can provide a simple and repeatable process of assembling and/or mounting an electronic device to a desired structure.

In one embodiment, the attaching step includes the accessory device 1004 having a hook set connection at a lower section 1012 and a fastener connection 1024 at an upper section 1010. This step provides a secure and robust structure that can help to facilitate attachment between the accessory device 1004 and the clamp support portion 118.

In one embodiment, the attaching step includes configuring a portion of the accessory device 1004 to be generally complementarily configured to substantially securely mate within an accessory attachment channel 1006 of the clamp support portion 118 for an enhanced and secure connection or installation.

In one embodiment, the latching step includes providing the latch mechanism on the first clamp portion 128 and the second clamp portion 136 to enable the latch mechanism to latch the clamp portions 128, 136 together after being positioned about or around the support structure 612. Advantageously, this provides an enhanced and secure connection to the support structure.

Referring again to FIGS. 2-6 and 8-14, an apparatus 100 for mounting an electronic device 602, 906 and an accessory device 902, 1004, 1008 to a support structure 612 includes a coupling member 102, a clamp member 104, and a latch mechanism. The coupling member 102 includes an elongated electronic device support portion 106 and a clamp support portion 118. The clamp support portion 118 extends substantially orthogonally from one end 110 of the electronic device support portion 106. The clamp support portion 118 includes a recessed outward-facing surface 1016 and defines an accessory attachment channel 1006 bordered on at least one side by the recessed outward-facing surface 1016. The clamp member 104 includes a base 122, a first clamp portion 128, a second clamp portion 136, and a hinge (as implemented in an exemplary manner through the interleaving member 140 and the hinge pin 504). The clamp member's base 122 is coupled to the clamp support portion 118 of the coupling member 102, and the hinge pivotally couples the first end 132 of the first clamp portion 128 to the first end 138 of the second clamp portion 136. In some embodiments, as illustrated in FIG. 5, the first and second clamp portions are arched. The latch mechanism is positioned at the second end 134 of the first clamp portion 128 and the second end 142 of the second clamp portion 136. The latch mechanism is configured to latch the second end 134 of the first clamp portion 128 to the second end 142 of the second clamp portion 136 after the first clamp portion 128 and the second clamp portion 136 are positioned about the support structure 612.

According to some exemplary embodiments, the recessed outward-facing surface 1016 of the coupling member's clamp support portion 118 defines a hook receiving aperture 1040 configured to receive a hook member 1018 of the accessory device 902, 1004, 1008 during installation of the accessory device in the accessory attachment channel 1006. In some of these embodiments, the recessed outward-facing surface 1016 of the clamp support portion 118 may optionally include a plurality of tapered surfaces 1050 configured to at least partially define the hook receiving aperture 1040. The tapering of such surfaces 1050 may be such that the hook receiving aperture 1040 is widest at its entry point from the accessory attachment channel 1006. In those embodiments where the hook receiving aperture 1040 is included, the recessed outward-facing surface 1016 of the clamp support portion 118 preferably defines or includes the hook receiving aperture 1040 in a lower portion of the accessory attachment channel 1006. For example, the hook receiving aperture 1040 may be defined or included in a lower half or a lower third of the recessed outward-facing surface 106 of the clamp support portion 118.

According to other exemplary embodiments, the coupling member's clamp support portion 118 defines a slot 126 configured to receive a protrusion 124 on a side of the base 122 of the clamp member 104. In some such embodiments, the slot 126 is longer than the protrusion 124, thereby facilitating adjustment (e.g., vertical adjustment) of the position of the clamp member 104 relative to the position of the coupling member's electronic device support portion 106.

According to other exemplary embodiments, the clamp member 104 further includes a first bushing component 514 attached to an inner face of the first clamp portion 128 and a second bushing component 516 attached to an inner face of the second clamp portion 136.

According to further exemplary embodiments, the clamp member's second clamp portion 136 has an outward radial extension 160 at its second end 142, which defines a slot 164. In these embodiments and as discussed above with respect to FIGS. 2 and 5, the latch mechanism optionally includes a threaded rod 152 and a latch nut 156. A first end of the threaded rod 152 is coupled to the second end of the first clamp portion 128 at a hinge joint. The latch nut 156 is disposed on the threaded rod 152 so as to be on an outer side of the outward radial extension 160 when the threaded rod 152 is rotated about the hinge joint and positioned in the slot 164 of the outward radial extension 160 to permit tightening of the latch nut 156 against the outer side of the outward radial extension 160.

According to other exemplary embodiments, the coupling member's electronic device support portion 106 optionally includes a first shuttle 404 positioned proximate to a surface of the electronic device support portion 106 near the electronic device support portion's first end 108 and a second shuttle 406 positioned proximate to the surface of the electronic device support portion 106 near the electronic device support portion's second end 110. In these embodiments, the first shuttle 404 and the second shuttle 406 are configured to engage in respective tracks 616 formed in a housing 1008,1401 of the electronic device 602, 906.

According to other exemplary embodiments, an accessory device 902, 1004, 1008 configured for attachment to an apparatus 100, 1000 for mounting an electronic device 602, 906 and the accessory device to a support structure 612 includes a housing 1008, 1401 and a hook member 1018. The housing 1008, 1401 is sized and shaped to be inserted into an accessory attachment channel 1006 of the mounting apparatus 100, where the accessory attachment channel 1006 is bordered on at least one side by a recessed surface 1016. The hook member 1018 is integrated with or attached to the housing 1008, 1401 and configured for insertion through a hook receiving aperture 1040 of the recessed surface 1016. The hook member 1018 may optionally include a horizontal portion 1030 and a vertical portion 1032. When so configured, the hook member 1018 may be constructed of silicone or flexible plastic with sufficient flexibility to enable the hook member's vertical portion 1032 to engage one or more tapered surfaces 1050 defining the hook receiving aperture 1040, the hook member's horizontal portion 1030 to thereafter flex without breaking, and at least the hook member's vertical portion 1032 to thereafter pass through the hook receiving aperture 1040. After passing through the hook receiving aperture 1040, the hook member's vertical portion 1032 may engage an inner surface of the coupling member's clamp support portion 118 to prevent the hook member 1018 from being pulled back out of the hook receiving aperture 1040.

According to other exemplary embodiments, the accessory device housing 1008, 1401 defines an opening 1022 for receiving a fastener440 to facilitate fastening the housing 1008, 1401 to a clamp support portion 118 of the mounting apparatus 100, 1000.

In the absence of any specific clarification related to its express use in a particular context, where the terms “substantially,” “approximately,” “generally,” or “about” are used as modifiers in the present disclosure and any appended claims (e.g., to modify a structure, a dimension, a measurement, a direction, an orientation, or any other characteristic), it is understood that the characteristic may vary by up to thirty percent. In these cases, a device that is mounted exactly orthogonal is mounted along a “Y” axis and a “X” axis that is normal (i.e., 90 degrees or at right angle) to a plane or line formed by a “Z” axis. Different from the exact precision of the term “orthogonal,” the use of “substantially” or “about” to modify the characteristic permits a variance of the particular characteristic by up to thirty percent or such other amount as may be required by the context of the applicable description. As another example, an element or component that is oriented exactly opposite to another element or component is oriented one hundred eighty degrees from the other element or component. Different from the exact precision of the term “opposite,” the use of “substantially” or “generally” to modify the orientation or direction permits a variance thereof by up to thirty percent (e.g., up to fifty-four degrees) or such other amount as may be stated in the applicable description or required by the context of the applicable description. Alternatively, these terms may refer to a range of numbers or quantities that one of skill in the art would consider equivalent to the recited values (i.e., having the same function or result). In many instances, these terms may include numbers that are rounded to the nearest significant figure.

The claims appended hereto are meant to cover all modifications and changes within the scope and spirit of the present disclosure.

What is claimed is:

1. An apparatus for mounting an electronic device and an accessory device to a support structure, the apparatus comprising:
a coupling member including an elongated electronic device support portion and a clamp support portion, the clamp support portion extending substantially orthogonally from one end of the electronic device support portion, the clamp support portion including a recessed outward-facing surface and defining an accessory attachment channel bordered on at least one side by the recessed outward-facing surface;
a clamp member including a base, a first clamp portion, a second clamp portion, and a hinge, the base being coupled to the clamp support portion of the coupling member, the hinge pivotally coupling a first end of the first clamp portion to a first end of the second clamp portion; and
a latch mechanism positioned at a second end of the first clamp portion and a second end of the second clamp portion, the latch mechanism configured to latch the second end of the first clamp portion to the second end of the second clamp portion after the first clamp portion and the second clamp portion are positioned about the support structure.

2. The apparatus of claim 1, wherein the recessed outward-facing surface of the clamp support portion defines a hook receiving aperture configured to receive a hook member of the accessory device during installation of the accessory device in the accessory attachment channel.

3. The apparatus of claim 2, wherein the recessed outward-facing surface of the clamp support portion includes a plurality of tapered surfaces configured to at least partially define the hook receiving aperture.

4. The apparatus of claim 3, wherein tapering of the plurality of tapered surfaces is such that the hook receiving aperture is widest at an entry point from the accessory attachment channel.

5. The apparatus of claim 2, wherein the recessed outward-facing surface of the clamp support portion defines the hook receiving aperture in a lower portion of the accessory attachment channel.

6. The apparatus of claim 2, wherein the hook receiving aperture is in a lower half of the recessed outward-facing surface of the clamp support portion.

7. The apparatus of claim 2, wherein the hook receiving aperture is in a lower third of the recessed outward-facing surface of the clamp support portion.

8. The apparatus of claim 1, wherein the clamp support portion further defines a slot configured to receive a protrusion on a side of the base of the clamp member.

9. The apparatus of claim 1, wherein the slot is longer than the protrusion, thereby facilitating adjustment of a position of the clamp member relative to a position of the electronic device support portion of the coupling member.

10. The apparatus of claim 1, wherein the clamp member further includes:
a first bushing component attached to an inner face of the first clamp portion; and
a second bushing component attached to an inner face of the second clamp portion.

11. The apparatus of claim 1, wherein the second clamp portion has an outward radial extension at the second end thereof, the outward radial extension defining a slot, and wherein the latch mechanism includes:
a threaded rod having a first end and a second end, the first end of the threaded rod being coupled to the second end of the first clamp portion at a hinge joint; and
a latch nut disposed on the threaded rod so as to be on an outer side of the outward radial extension when the threaded rod is rotated about the hinge joint and positioned in the slot of the outward radial extension to permit tightening of the latch nut against the outer side of the outward radial extension.

12. The apparatus of claim 1, wherein the electronic device support portion of the coupling member further includes:
a first shuttle positioned proximate a surface of the electronic device support portion at the first end of the electronic device support portion; and
a second shuttle positioned proximate the surface of the electronic device support portion at the second end of the electronic device support portion, wherein the first shuttle and the second shuttle are configured to engage in respective tracks formed in a housing of the electronic device.

13. The apparatus of claim 1, wherein the first clamp portion and the second clamp portion are arched.

14. An accessory device configured for attachment to an apparatus for mounting an electronic device and the accessory device to a support structure, the accessory device comprising:
a housing sized and shaped to be inserted into an accessory attachment channel of the mounting apparatus, the accessory attachment channel being bordered on at least one side by a recessed surface; and
a hook member integrated with or attached to the housing, the hook member being configured for insertion through a hook receiving aperture of the recessed surface.

15. The accessory device of claim 14, wherein the hook member includes a horizontal portion and a vertical portion.

16. The accessory device of claim 15, wherein the wherein the hook member has sufficient flexibility to enable the vertical portion to engage at least one tapered surface of a plurality of tapered surfaces configured to at least partially define the hook receiving aperture, the horizontal portion to thereafter flex without breaking, and at least the vertical portion to thereafter pass through the hook receiving aperture.

17. The accessory device of claim 14, wherein the housing defines an opening for receiving a fastener to facilitate fastening the housing to a clamp support portion of the mounting apparatus.
